(19) United States
(12) Patent Application Publication
(10) Pub. No.: US 2025/0323230 A1
(43) Pub. Date: Oct. 16, 2025

(54) SEMICONDUCTOR PACKAGE STRUCTURE COMPRISING PHOTONIC IC CHIP ADJACENT TO ELECTRICAL IC CHIP

(71) Applicant: Taiwan Semiconductor Manufacturing Company, Ltd., Hsinchu (TW)

(72) Inventor: Chan-Hong Chern, Palo Alto, CA (US)

(21) Appl. No.: 19/250,140

(22) Filed: Jun. 26, 2025

Related U.S. Application Data
(63) Continuation of application No. 18/432,337, filed on Feb. 5, 2024.
(60) Provisional application No. 63/519,864, filed on Aug. 16, 2023.
(60) Provisional application No. 63/584,548, filed on Sep. 22, 2023.

(51) Int. Cl. H01L 25/16; G02B 6/42; G02B 6/43; H01L 23/00; H01L 23/31; H01L 23/367; H10B 80/00

(52) U.S. Cl. CPC H01L 25/167; G02B 6/4202; G02B 6/43; H01L 23/3107; H01L 23/367; H01L 24/16; H01L 24/29; H01L 24/32; H01L 24/73; H01L 24/81; H10B 80/00; H01L 2224/16145; H01L 2224/16227; H01L 2224/29082; H01L 2224/2957; H01L 2224/32245; H01L 2224/73253; H01L 2224/81805; H01L 2924/1432; H01L 2924/1435

(57) ABSTRACT

Various embodiments of the present disclosure are directed towards a semiconductor package structure including a first integrated circuit (IC) chip overlying a base structure. An electrical IC chip overlies the base structure and is disposed around the first IC chip. The electrical IC chip is electrically coupled to the first IC chip. A photonic IC chip overlies the base structure and is electrically coupled to the electrical IC chip. The photonic IC chip is configured to receive an input optical signal. The photonic IC chip is adjacent to the electrical IC chip.

### REFERENCE TO RELATED APPLICATIONS

This Application is a Continuation of U.S. application Ser. No. 18/432,337, filed on Feb. 5, 2024, which claims the benefit of U.S. Provisional Application No. 63/519,864, filed on Aug. 16, 2023 and U.S. Provisional Application No. 63/584,548, filed on Sep. 22, 2023. The contents of the above-referenced Patent Applications are hereby incorporated by reference in their entirety.

### BACKGROUND

A system-in-package (SiP) may include multiple integrated circuit (IC) chips packaged together. The IC chips implement functional blocks of the SiP. In order to facilitate high frequency and/or high data rates, the SiP includes an electrical IC chip integrated with a photonic IC chip. Among other things, the integration of the electrical and photonic IC chips may reduce energy loss, increase an overall performance of the SiP, and allow smaller components.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of some embodiments of a semiconductor package structure comprising a photonic integrated circuit (IC) chip directly adjacent to an electrical IC chip.

FIG. 2 illustrates a cross-sectional view of some embodiments of a semiconductor package structure comprising a photonic IC chip directly overlying an electrical IC chip.

FIG. 3A illustrates a cross-sectional view of some other embodiments of the semiconductor package structure of FIG. 1.

FIGS. 3B and 3C illustrate various top views of some embodiments of the semiconductor package structure of FIG. 3A.

FIG. 4A illustrates a cross-sectional view of some other embodiments of the semiconductor package structure of FIG. 2.

FIGS. 4B and 4C illustrate various top views of some embodiments of the semiconductor package structure of FIG. 4A.

FIG. 5A illustrates a cross-sectional view of some other embodiments of the semiconductor package structure of FIG. 3A.

FIGS. 5B and 5C illustrate various top views of some embodiments of the semiconductor package structure of FIG. 5A.

FIG. 6A illustrates a cross-sectional view of some other embodiments of the semiconductor package structure of FIG. 4A.

FIGS. 6B and 6C illustrate various top views of some embodiments of the semiconductor package structure of FIG. 6A.

FIGS. 7A-7E illustrate various cross-sectional views of some embodiments of a semiconductor package structure comprising a heat dissipation structure overlying a plurality of IC chips.

FIGS. 8A-8E illustrate various cross-sectional views of some embodiments of a semiconductor package structure comprising a heat dissipation structure overlying a plurality of IC chips, where the heat dissipation structure comprises a heat sink structure over a liquid cooling structure.

FIGS. 9-17 illustrate cross-sectional views of some embodiments of a method for forming a semiconductor package structure that includes a photonic IC chip directly adjacent to an electrical IC chip.

FIG. 18 illustrates a flow diagram of some embodiments of a method of forming a semiconductor package structure that includes a photonic IC chip directly adjacent to an electrical IC chip.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A system-in-package (SiP) with a chiplet design may comprise a plurality of integrated circuit (IC) chiplets packaged together. For example, the SiP may comprise a memory IC chiplet, an electrical IC chiplet (e.g., comprising one or more processors such as a graphics processing unit (GPU), a central processing unit (CPU), etc.), and a photonic IC chiplet packaged together on a package substrate. The IC chiplets implement functional blocks of the SiP and communicate electrically with one another. The photonic IC chiplet utilizes optical signals to provide high speed signal communication. The use of optical signals provides lower power consumption and generates less heat compared to electrical signals. As a result, the SiP may operate at high frequencies and/or high data rates with reduced heat and reduced transmission loss.

The photonic IC chiplet is configured to generate and/or detect optical signals and transform the optical signals to electrical signals (or vice versa) that are then provided to the electrical IC chiplet. The SiP includes an interposer over a package substrate that facilitates electrical connections between the electrical IC chiplet and the photonic IC chiplet by way of conductive interconnect structures. The IC chiplets overlie the interposer. To facilitate high processing performance of the electrical IC chiplet, the memory IC chiplet is disposed directly adjacent to the electrical IC chiplet. For example, one or more memory IC chiplets may laterally surround and be directly laterally adjacent to the electrical IC chiplet. This decreases a distance electrical signals travel between the memory and electrical IC chiplets, thereby increasing transmission efficiency and speed between the two IC chiplets. One or photonic IC chiplets are spaced at corners of the electrical IC chiplet and/or the memory IC chiplet is spaced laterally between the photonic IC chiplet and the electrical IC chiplet. However, this increases a distance electrical signals travel between the photonic IC chiplet and the electrical IC chiplet. The increased distance increases a number and/or size of conductive interconnect structures disposed in the interposer and/or individual IC chiplets to carry the electrical signals. Further, electrical signals utilize high power to travel large distances (e.g., due to losses in the conductive interconnect structures). As a result, power consumption, heat generation, and latency are increased, thereby decreasing a transmission efficiency and an overall performance of the SiP.

In another example, the photonic IC chiplet is spaced laterally between the electrical IC chiplet and the memory IC chiplet. This increases transmission efficiency between the electrical and photonic IC chiplets, but decreases the processing performance of the electrical IC chiplet (e.g., because of an increased delay in accessing data from the memory IC chiplet). Further, in such an example, optical signals are transmitted to and/or received by the photonic IC chiplet at an upper surface of the photonic IC chiplet (e.g., by a grating coupler). However, grating couplers are wavelength sensitive and may reduce optical coupling. In addition, the transmission and/or receiving of the optical signals in the vertical direction reduces an ability to integrate a heat dissipation structure over the SiP, thereby decreasing an overall performance and reliability of the SiP.

Various embodiments of the present disclosure are directed towards a semiconductor package structure having a photonic IC chip directly adjacent to an electrical IC chip. The semiconductor package structure comprises an interposer over a package substrate. A memory IC chip and the electrical IC chip overlie the interposer and are electrically coupled to one another. The memory IC chip is spaced between sidewalls of the electrical IC chip. The photonic IC chip overlies the interposer and is directly adjacent to the electrical IC chip. In an embodiment, the photonic IC chip is directly laterally adjacent to the electrical IC chip. In another embodiment, the photonic IC chip directly overlies the electrical IC chip. Accordingly, a distance electrical signals travel between the photonic IC chip and the electrical IC chip is decreased, thereby increasing transmission efficiency. Further, the photonic IC chip is disposed at a peripheral region of the interposer and comprises input/output (I/O) couplers (e.g., edge couplers) configured to receive optical signals at least one side of the photonic IC chip. This facilitates the transmission and/or receiving of optical signals in the horizontal direction such that a heat dissipation apparatus may be disposed over the memory and/or electrical IC chips. As a result, high heat generated during operation of the semiconductor package structure may be efficiently dissipated away from the IC chips, thereby increasing an overall performance and reliability of the semiconductor package structure.

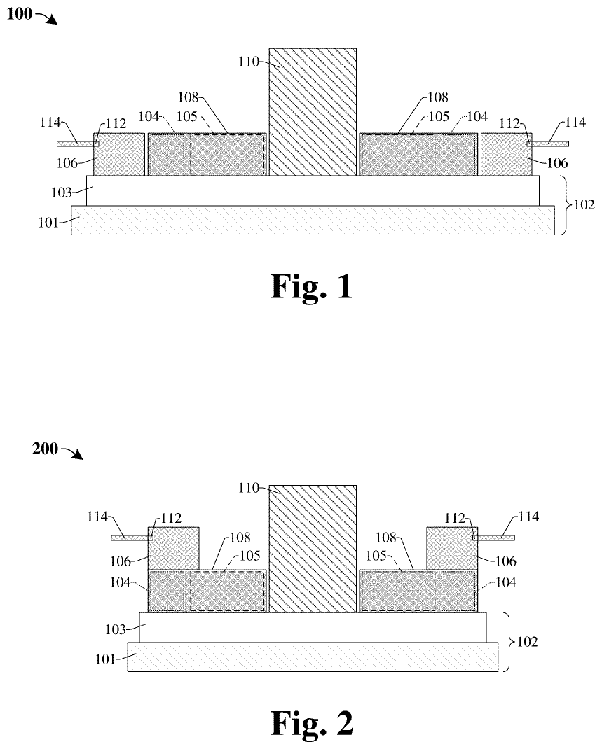

FIG. 1 illustrates a cross-sectional view 100 of some embodiments of a semiconductor package structure including a photonic integrated circuit (IC) chip 106 directly adjacent to an electrical IC chip 108.

The semiconductor package structure includes a base structure 102. The base structure 102 includes an interposer 103 overlying a package substrate 101. In some embodiments, the semiconductor package structure further includes a plurality of IC chips 106, 108, 110 that comprises photonic IC chips 106, electrical IC chips 108, and a memory IC chip 110 overlying the base structure 102. The photonic IC chips 106, the electrical IC chips 108, and the memory IC chip 110 are each configured to implement one or more individual functional blocks of the semiconductor package structure. In some embodiments, each of the IC chips 106, 108, 110 may be referred to as an IC chiplet. In some embodiments, the IC chips 106, 108, 110 of the semiconductor package structure are disposed in a 2.5D structure, where each of the IC chips 106, 108, 110 are disposed at a same elevation and/or have bottom surfaces coplanar with one another.

The photonic IC chips 106, the electrical IC chips 108, and the memory IC chip 110 are coupled (e.g., electrically coupled) together through electrical input/output (I/O) structures on the interposer 103 (not shown). The interposer 103 comprises conductive interconnect routing, through substrate vias (TSVs), contact pads, or the like (not shown) configured to integrate the photonic IC chips 106, the electrical IC chips 108, and the memory IC chip 110 together. The photonic IC chips 106 are disposed at a peripheral of the interposer 103 and each comprise an optical I/O structure 112 disposed at an outer edge of the photonic IC chip 106. The optical I/O structure 112 is configured to facilitate receiving and/or transmitting optical signals from and/or to an optical fiber structure 114. In some embodiments, the optical fiber structure 114 is coupled to light source (not shown) configured to transmit optical signals to the photonic IC chips 106. In yet further embodiments, the optical fiber structure 114 is coupled to a light receiver circuit (not shown) configured to receive an optical signal from the optical I/O structure 112 of the photonic IC chips 106. In various embodiments, the photonic IC chips 106 further respectively include structures or devices (not shown) that can generate optical signals, detect optical signals, modify optical signals, transfer optical signals, and/or transform optical signals to electrical signals (or vice versa). For example, the photonic IC chips 106 may include waveguides, photodetectors, lasers, optical modulators, other photonic devices, or any combination of the foregoing.

In some embodiments, the electrical IC chips 108 are each configured as a system-on-chip (SoC) chip and comprise an electrical integrated circuit (EIC) 104 and a functional IC 105. In various embodiments, the EIC 104 and the functional IC 105 may be or comprise one or more chiplets on the SoC, where the SoC has a chiplet design. The EIC 104 is electrically coupled to the photonic IC chip 106 by way of the interposer 103. In various embodiments, the EIC 104 is configured to receive an electrical signal from the photonic IC chip 106 that corresponds to an optical signal received from the optical fiber structure 114. In further embodiments, the EIC 104 is configured to perform signal processing (e.g., amplify, filter, etc.) on the electrical signal from the photonic IC chip 106 and provide the output electrical signal to the functional IC 105 for further processing. Thus, the EIC 104 provides an electrical interface between the functional IC 105 and the photonic IC chip 106, and the photonic IC chip 106 provides an electrical interface between the EIC 104 and the optical fiber structure 114. The functional IC 105 may, for example, be or comprise a switch chip, an application-specific integrated circuit (ASIC), a central processing unit (CPU), a graphics processing unit (GPU), a data processing unit (DPU), and so on. The functional IC 105 is configured to receive the output electrical signal from the EIC 104. By embedding the EIC 104 with the functional IC 105 on the same chip (i.e., on the electrical IC chip 108), transmission loss of the output electrical signal is reduced, thereby increasing transmission efficiency.

The memory IC chip 110 is disposed directly adjacent to the electrical IC chip 108. In some embodiments, the memory IC chip 110 is electrically coupled to the electrical IC chip 108 by way of the interposer 103. In some embodiments, the memory IC chip 110 comprises a memory controller circuit and one or more high-bandwidth memory layers. The memory IC chip 110 is configured to provide and/or store data to/from the functional IC 105. The memory IC chip 110 being disposed directly adjacent to the electrical IC chip 108 increases transmission efficiency between the memory IC chip 110 and the electrical IC chip 108. As a result, a speed at which the electrical IC chip 108 (e.g., the IC chip) may process stored data and/or write data is increased. For example, when the functional IC 105 is or comprises a GPU, the increased transmission efficiency between the memory IC chip 110 and the electrical IC chip 108 increases a number of floating-point operations performed by the GPU each second.

By virtue of the photonic IC chip 106 being disposed directly laterally adjacent to the electrical IC chip 108, a distance electrical signals travel between the photonic IC chip 106 and the electrical IC chip 108 is decreased. This facilitates decreasing a number of conductive routing structures in the interposer 103, decreases power consumption, and decreases transmission loss, thereby increasing transmission efficiency between the photonic IC chip 106 and the electrical IC chip 108. In addition, the IC chips 106, 108, 110 being disposed at the same elevation (i.e., the semiconductor package structure having the 2.5D structure) decreases an overall height of the semiconductor package structure. As a result, a size of the the semiconductor package structure may be reduced.

FIG. 2 illustrates a cross-sectional view 200 of some alternative embodiments of the semiconductor package structure of FIG. 1 in which the photonic IC chips 106 directly overlie a corresponding electrical IC chip 108. The photonic IC chips 106 directly overlie at least a portion of the EIC 104 of the electrical IC chip 108. In an embodiment, the photonic IC chips 106 may be directly electrically coupled to the EIC 104 by way of a plurality of solder balls or a plurality of solder microbumps disposed between the photonic IC chips 106 and the electrical IC chips 108. In another embodiment, the photonic IC chips 106 and the electrical IC chips 108 respectively comprise hybrid bond structures that facilitate electrically coupling between the photonic and electrical IC chips 106, 108.

In some embodiments, disposing the photonic IC chips 106 directly on the electrical IC chip 108 further decreases a distance an electrical signal travels between the photonic and electrical IC chips 106, 108. As a result, transmission efficiency is further improved and a power consumption of the semiconductor package structure is decreased. In addition, a number of conductive interconnect structures in the interposer 103 is decreased, thereby decreasing a design complexity and/or a lateral footprint of the semiconductor package structure.

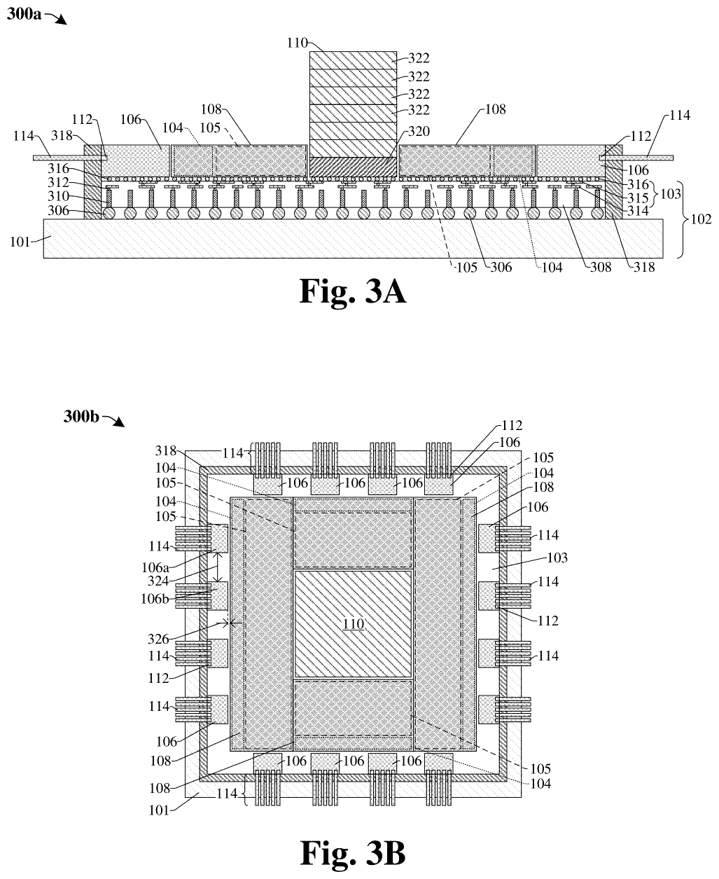

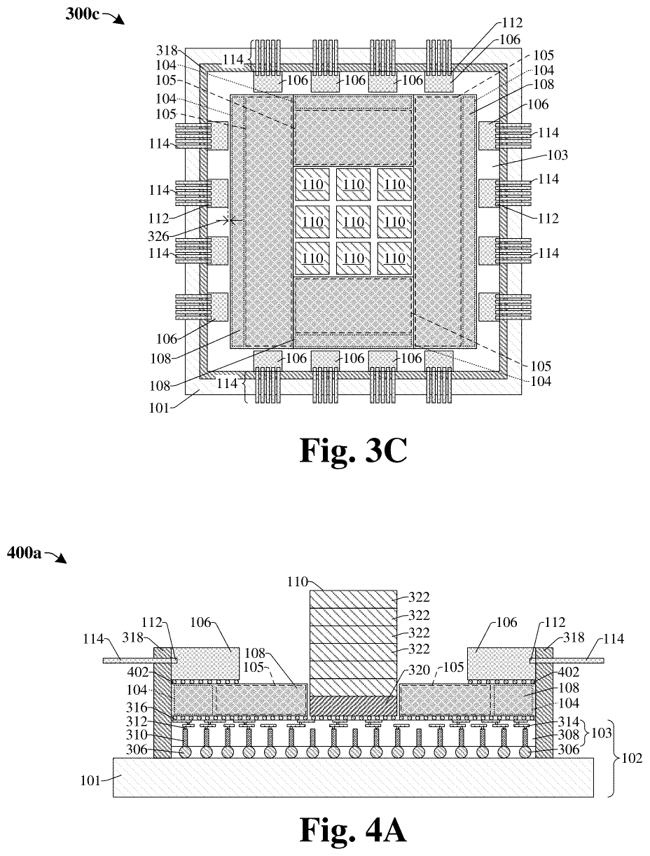

FIG. 3A illustrates a cross-sectional view 300a of some other embodiments of the semiconductor package structure of FIG. 1.

The semiconductor package structure includes a plurality of IC chips 106, 108, 110 disposed over a base structure 102. The base structure 102 comprises an interposer 103 overlying a package substrate 101. In some embodiments, the package substrate 101 is or comprises a printed circuit board (PCB) substrate or some other suitable substrate. The interposer 103 comprises an interposer structure 308, a plurality of through substrate vias (TSVs) 310, a plurality of conductive interconnect structures 312, 314, and a plurality of contact pads 315. In various embodiments, the interposer structure 308 comprises a substrate (e.g., a silicon substrate) and a dielectric structure, where the TSVs 310 are disposed in the substrate and the plurality of conductive interconnect structures 312, 314 and the contact pads 315 are disposed in the dielectric structure. Conductive features of the interposer 103 are configured to electrically couple the IC chips 106, 108, 110 to one another and to the package substrate 101. A plurality of first solder bumps 306 are disposed between the interposer 103 and the package substrate 101. The first solder bumps 306 facilitate bonding and electrical coupling between the interposer 103 and the package substrate 101. In further embodiments, the interposer 103 may be electrically coupled to the package substrate 101 by way of wire bonding (not shown).

The plurality of IC chips 106, 108, 110 overlie the interposer 103. A plurality of second solder bumps 316 are disposed between the interposer 103 and the plurality of IC chips 106, 108, 110. The second solder bumps 316 facilitate bonding and electrical coupling between the interposer 103 and the plurality of IC chips 106, 108, 110. In various embodiments, the second solder bumps 316 may be omitted (not shown) and bond pads of the plurality of IC chips 106, 108, 110 may be directly bonded to the contact pads 315 of the interposer 103. Accordingly, the interposer 103 is configured to integrate the IC chips 106, 108, 110 together.

The plurality of IC chips 106, 108, 110 include one or more photonic IC chips 106, one or more electrical IC chips 108, and one or more memory IC chips 110. In various embodiments, the semiconductor package structure has a 2.5D design where the IC chips 106, 108, 110 are placed side-by-side and are disposed at a same elevation and along a same plane overlying the interposer 103. In such an embodiment, bottom surfaces of the IC chips 106, 108, 110 are substantially aligned with one another. In yet further embodiments, bottom surfaces of the IC chips 106, 108, 110 are each coplanar or substantially coplanar with one another.

In some embodiments, the one or more memory IC chips 110 are or comprise a plurality of memory layers 322 vertically stacked with a memory controller circuit 320. The plurality of memory layers 322 may, for example, be or comprise high-bandwidth memory that may be read from and/or written to by the electrical IC chips 108 in conjunction with the memory controller circuit 320. The memory controller circuit 320 comprises circuitry (e.g., transistors, etc.) configured to read from and/or write to the plurality of memory layers 322. In some embodiments, the memory layers 322 comprise one or more of high bandwidth memory (HBM), static random access memory (SRAM), dynamic random access memory (DRAM), non-volatile memory (NVM), three dimensional (3D) memory, compute-in-memory (CIM), some other suitable memory, or any combination of the foregoing. For example, the memory layers 322 comprise a plurality of memory devices that may be or comprise transistors, resistive random-access memory (RRAM) cells, phase-change memory (PCM) cells, magnetoresistive random access memory (MRAM) cells, some other suitable semiconductor devices, or any combination of the foregoing. In various embodiments, the electrical IC chips 108 are configured to send a control signal and/or data to the memory controller circuit 320 and the memory controller circuit 320 is configured to write data to and/or read data from the memory layers 322 based on the control signal and/or data provided by the electrical IC chips 108. In some embodiments, the memory controller circuit 320 is configured to provide stored data to the electrical IC chips 108 based at least in part on the control signal.

In some embodiments, the one or more electrical IC chips 108 are configured as a system-on-chip (SoC) chip and include an electrical integrated circuit (EIC) 104 and a functional IC 105. The electrical IC chips 108 are electrically coupled to the photonic IC chips 106 by way of the interposer 103. The EIC 104 is spaced laterally between a corresponding photonic IC chip 106 and the functional IC 105, thereby increasing transmission efficiency between the EIC 104 and the photonic IC chip 106. In some embodiments, the EIC 104 comprises circuitry including amplifier circuits, driver circuits, control circuits, digital processing circuits, etc. The EIC 104 is configured to receive an electrical signal from the photonic IC chip 106 that corresponds to a received optical signal. Further, the EIC 104 comprises circuitry or other structures to generate electrical signals to control and/or provide power to components of the photonic IC chip 106.

The functional IC 105 may, for example, be or comprise one or more of a switch chip, an ASIC, a CPU, a GPU, a DPU, and so on. The functional IC 105 is configured to receive an output electrical signal from the EIC 104 that corresponds to the received optical signal at the photonic IC chip 106. In various embodiments, the functional IC 105 is or comprises one or more of a digital circuit, an analog circuit, a mixed-signal circuit, and so one. In some embodiments, circuits of the functional IC 105 include complementary metal-oxide semiconductor (CMOS) transistors, planar CMOS transistors, fin field-effect transistors (FinFETs), gate-all-around (GAA) transistors, nanosheet transistors, a two-dimensional (2D) semiconductor materials, some other electronic device, or any combination of the foregoing. In various embodiments, the functional IC 105 comprises one or more processor circuits configured to perform operations on the output electrical signal from the EIC 104 and/or stored data from the memory IC chip 110. In some embodiments, devices of the EIC 104 and devices of the functional IC 105 are disposed on a same semiconductor substrate and are electrically coupled to one another by a single interconnect structure. As a result, transmission loss of electrical signals between the EIC 104 and the functional IC 105 is reduced, thereby increasing a performance of the one or more electrical IC chips 108.

The photonic IC chips 106 are disposed at a peripheral of the interposer 103. The photonic IC chips 106 comprise one or more optical I/O structures 112 and other photonic devices such as waveguides, photodetectors, light emitting units (e.g., laser diodes, light emitting diodes, etc.), optical modulators, other photonic devices, or any combination of the foregoing. The optical I/O structure 112 is disposed at an outer edge of the photonic IC chip 106 and is configured to receive and/or transmit optical signals from and/or to an optical fiber structure 114. A housing structure 318 is disposed at opposing ends of the interposer 103. In some embodiments, the housing structure 318 comprises openings aligned with the optical I/O structure 112 and is configured to provide support for the optical fiber structure 114. In some embodiments, the optical fiber structure 114 one or more optical fibers that may each be a single-mode or multi-mode optical fiber. In various embodiments, the optical I/O structures 112 may each be or comprise an edge coupler or some other suitable optical I/O structure. In such embodiments, the edge coupler may comprise a plurality of optical core segments that are polarization independent such that the edge coupler may receive a wide range of wavelengths, thereby increasing coupling efficiency between the optical I/O structure 112 and a corresponding optical fiber structure 114.

The photonic IC chips 106 are configured to utilize optical signals to provide high speed signal communication for the semiconductor package structure with external IC devices. The use of optical signals provides lower power consumption and generates less heat compared to communicating with the external IC devices via electrical signals. As a result, the photonic IC chips 106 facilitate the semiconductor package structure operating at high frequencies and/or high data rates with reduced heat and reduced transmission loss.

During use of the semiconductor package structure, optical signals received from an external device (e.g., comprising a light source) at one end of the optical fiber structure 114 is transmitted to the optical I/O structure 112. In some embodiments, the photonic IC chip 106 comprises a waveguide optically coupled to the optical I/O structure 112 and a photodetector optically coupled to the waveguide. An input optical signal travels from the optical I/O structure 112 through the waveguide to the photodetector. The photodetector is configured to convert the input optical signal from the optical fiber structure 114 to a detected electrical signal that is provided to the EIC 104. For example, the detected electrical signal from the photodetector may be provided to circuitry (e.g., an amplifier circuit) of the EIC 104 by way of interconnect structures in the photonic and electrical IC chips 106, 108 and the interposer 103. The EIC 104 is configured to receive the detected electrical signal and generate an output electrical signal that corresponds to the input optical signal. The EIC 104 then provides the output electrical signal to the functional IC 105. In various embodiments, the functional IC 105 is configured to perform processing operations on the output electrical signal, generate control signals from the output electrical signal, and so on. Thus, the EIC 104 provides an electrical interface between the functional IC 105 and the photonic IC chip 106.

In various embodiments, by virtue of the photonic IC chip 106 and the electrical IC chip 108 being disposed at a same elevation, photonic devices (e.g., the waveguide, photodetector, etc.) of the photonic IC chip 106 are vertically aligned with (i.e., disposed along a same plane as) electrical devices (e.g., transistors) of the EIC 104 and/or electrical devices (e.g., transistors) of the functional IC 105. In various embodiments, the photonic IC chip 106 and the EIC 104 are disposed on separate IC chips from one another. In such an embodiment, the photonic devices (e.g., waveguides, photodetectors, laser, optical modulators, optical I/O structures 112, etc.) of the photonic IC chip 106 are disposed on a first substrate and the electrical devices (e.g., transistors) of the EIC 104 are disposed on a second substrate different from and/or separate from the first substrate.

In addition, during use of the semiconductor package structure, the EIC 104 may provide control and/or power signals (e.g., by way of a driver circuit) to light emitting units and/or optical modulators on the photonic IC chip 106. The photonic IC chip 106 is configured to generate an output optical signal based on the control and/or power signals provided by the EIC 104. For example, the output optical signal is generated by a light emitting unit of the photonic IC chip 106 and travels across a waveguide to the optical I/O structure 112. In various embodiments, an optical modulator disposed in the photonic IC chip 106 is configured to modulate the output optical signal according to the control and/or power signals from the EIC 104. The optical I/O structure 112 provides the output optical signal to the optical fiber structure 114 which is further transmitted to the external device.

Each photonic IC chip 106 is directly adjacent to a corresponding electrical IC chip 108. For example, the photonic IC chip 106 is directly laterally adjacent to the electrical IC chip 108, where a lateral distance between the photonic IC chip 106 and corresponding electrical IC chip 108 is substantially small or zero. In some embodiments, a sidewall of the photonic IC chip 106 directly contacts a sidewall of the electrical IC chip 108. In another embodiment, the lateral distance between the photonic IC chip 106 and the corresponding electrical IC chip 108 is less than about 0.1% to 5% of a width of the photonic IC chip 106. As a result of the photonic IC chip 106 being spaced directly laterally adjacent to the electrical IC chip 108, a distance electrical signals travel between the photonic and electrical IC chips 106, 108 is reduced. This simplifies electrical routing between the photonic and electrical IC chips 106, 108, decreases power consumption, and decreases transmission loss, thereby increasing transmission efficiency between the photonic and electrical IC chips 106, 108 and decreasing a power consumption of the semiconductor package structure. Further, the EIC 104 is advantageously spaced between the photonic IC chip 106 and the functional IC 105. This facilitates the EIC 104 efficiently providing output electrical signals, that correspond to input optical signals received at the photonic IC chip 106, to the functional IC 105 with minimal transmission loss. Thus, the layout and/out placement of the plurality of IC chips 106, 108, 110 as described above increases an overall performance of the semiconductor package structure.

In some embodiments, a lateral distance between each photonic IC chip in the plurality of photonic IC chips 106 and the one or more electrical IC chips 108 is less than half a width of an individual IC photonic IC chip 106. In yet further embodiments, an outer sidewall of each photonic IC chip in the plurality of photonic IC chips 106 is aligned with a corresponding sidewall of the interposer 103.

FIG. 3B illustrates a top view 300b of some embodiments of the semiconductor package structure of FIG. 3A.

As illustrated in FIG. 3B, the one or more electrical IC chips 108 laterally surround the memory IC chip 110. In some embodiments, the memory IC chip 110 is spaced between opposing sidewalls of the one or more electrical IC chips 108. In various embodiments, the electrical IC chips 108 are illustrated as multiple independent chips disposed around an outer perimeter of the memory IC chip 110. In further embodiments, it will be appreciated that the electrical IC chips 108 are a single IC chip having an opening in a center region of the single IC chip, where the memory IC chip 110 is disposed in the opening. In some embodiments, the housing structure 318 surrounds an outer perimeter of the interposer 103 and provides support for the optical fiber structures 114. The plurality of photonic IC chips 106 are disposed around the outer perimeter of the one or more electrical IC chips 108. The photonic IC chips 106 are spaced directly adjacent to a corresponding EIC 104 of the one or more electrical IC chips 108. In some embodiments, the photonic IC chips 106 are spaced between an outer perimeter of the one or more electrical IC chips 108 and an outer perimeter of the interposer 103.

The plurality of photonic IC chips 106 comprises a first photonic IC chip 106a adjacent to a second photonic IC chip 106b. In some embodiments, a first lateral distance 324 between the first photonic IC chip 106a and the second photonic IC chip 106b is greater than a second lateral distance 326 between each photonic IC chip in the plurality of photonic IC chips 106 and the one or more electrical IC chips 108. In further embodiments, a lateral distance between the plurality of photonic IC chips 106 and the memory IC chip 110 is greater than the second lateral distance 326. In yet further embodiments, a lateral distance between the memory IC chip 110 and the one or more electrical IC chips 108 is less than the second lateral distance 326.

FIG. 3C illustrates a top view 300c of some other embodiments of the semiconductor package structure of FIG. 3A in which the semiconductor package structure comprises a plurality of memory IC chips 110 disposed in an array comprising columns and rows. The plurality of memory IC chips 110 that are spaced between opposing sidewalls of the one or more electrical IC chips 108. In various embodiments, a lateral distance between adjacent memory IC chips in the plurality of memory IC chips 110 is greater than the second lateral distance 326 between each photonic IC chip in the plurality of photonic IC chips 106 and the one or more electrical IC chips 108.

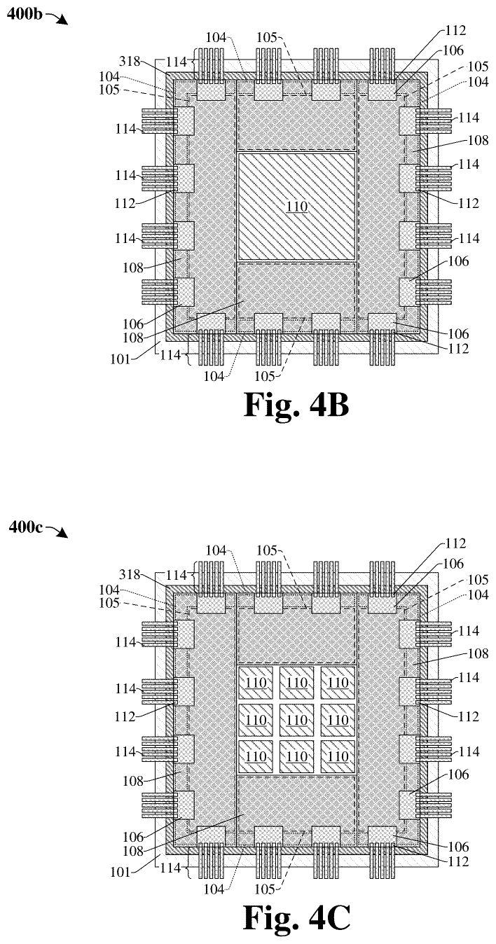

FIG. 4A illustrates a cross-sectional view 400a of some other embodiments of the semiconductor package structure of FIG. 2. In some embodiments, the semiconductor package structure of FIG. 4A may comprise some aspects of the semiconductor package structure in FIG. 3A (and vice versa); and thus, the features and/or reference numerals explained above with regards to FIG. 3A are also applicable to the semiconductor package structure of FIG. 4A.

Each photonic IC chip 106 is directly adjacent to a corresponding electrical IC chip 108. For example, the photonic IC chips 106 respectively directly overlie a corresponding electrical IC chip 108. In some embodiments, the semiconductor package structure comprises a plurality of third solder bumps 402 disposed along a top surface of the electrical IC chips 108. The third solder bumps 402 are disposed between each photonic IC chip 106 and an underlying electrical IC chip 108. The third solder bumps 402 provide electrical coupling between the photonic and electrical IC chips 106, 108. In yet further embodiments, the third solder bumps 402 are omitted (not shown) and a bonding structure of the photonic IC chip 106 directly contacts a bonding structure of the electrical IC chip 108. In such embodiments, a bottom surface of the photonic IC chips 106 directly contact a top surface of a corresponding electrical IC chip 108. Further, the photonic IC chips 106 respectively overlie a corresponding EIC 104 of the electrical IC chips 108 such that the photonic IC chips 106 are directly electrically coupled to the EICs 104.

In some embodiments, disposing the photonic IC chips 106 directly on the electrical IC chips 108 further decreases a distance an electrical signal travels between the photonic and electrical IC chips 106, 108. As a result, transmission efficiency is further improved and a power consumption of the semiconductor package structure is decreased, thereby increasing an overall performance of the semiconductor package structure. In some embodiments, the photonic IC chips 106 and the electrical IC chips 108 are vertically stacked with one another in a 3D structure and the electrical IC chips 108 and the memory IC chip 110 have a 2.5D structure. This, in part, decreases a lateral footprint of the semiconductor package structure.

FIG. 4B illustrates a top view 400b of some embodiments of the semiconductor package structure of FIG. 4A.

As illustrated in FIG. 4B, the one or more electrical IC chips 108 laterally surround the memory IC chip 110. In various embodiments, the electrical IC chips 108 are illustrated as multiple independent chips disposed around an outer perimeter of the memory IC chip 110. In further embodiments, it will be appreciated that the electrical IC chips 108 are a single IC chip having an opening in a center region of the single IC chip, where the memory IC chip 110 is disposed in the opening. The photonic IC chips 106 directly overlie the electrical IC chips 108.

FIG. 4C illustrates a top view 400c of some other embodiments of the semiconductor package structure of FIG. 4A in which the semiconductor package structure comprises a plurality of memory IC chips 110 disposed in an array comprising columns and rows. The plurality of memory IC chips 110 that are spaced between opposing sidewalls of the one or more electrical IC chips 108.

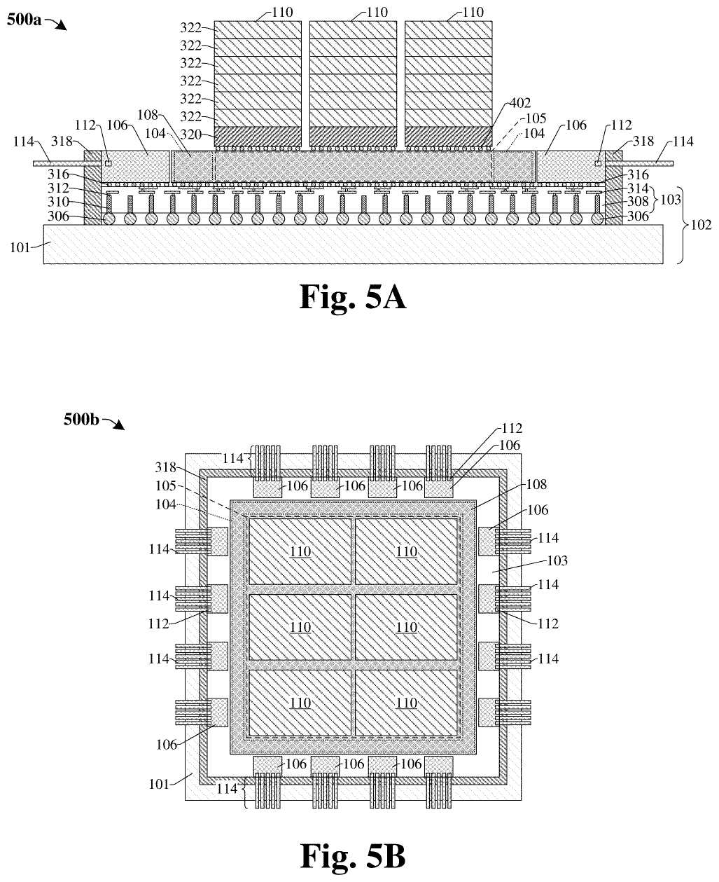

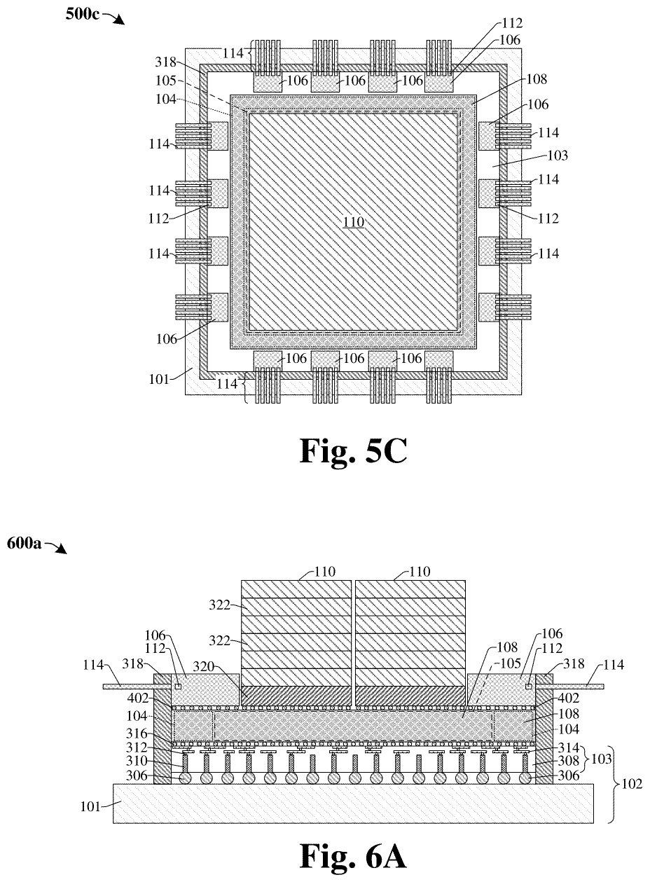

FIG. 5A illustrates a cross-sectional view 500a corresponding to some other embodiments of the semiconductor package structure of FIG. 3A in which the semiconductor package structure comprises a single electrical IC chip 108 and a plurality of memory IC chips 110.

In some embodiments, the electrical IC chip 108 is disposed over a central region of the interposer 103 and extends between photonic IC chips 106. The photonic IC chips 106 are disposed around an outer perimeter of the electrical IC chip 108. The electrical IC chip 108 comprises the functional IC 105 and the EIC 104. The functional IC 105 is disposed at a middle region of the electrical IC chip 108 and the EIC 104 is disposed at a peripheral region of the electrical IC chip 108 directly adjacent to the photonic IC chips 106. In various embodiments, the photonic IC chips 106 and the electrical IC chip 108 are disposed at a same elevation and the plurality of memory IC chips 110 directly overlie the electrical IC chip 108. The memory IC chips 110 are directly electrically coupled to the electrical IC chip 108. As a result, transmission efficiency between the memory IC chips 110 and the electrical IC chip 108 is increased.

FIG. 5B illustrates a top view 500b of some embodiments of the semiconductor package structure of FIG. 5A.

As illustrated in FIG. 5B, the EIC 104 laterally surrounds the functional IC 105. In some embodiments, the memory IC chips 110 directly overlie the functional IC 105 and is spaced between opposing sidewalls of the electrical IC chip 108. The photonic IC chips 106 are spaced around an outer perimeter of the electrical IC chip 108.

FIG. 5C illustrates a top view 500c of some other embodiments of the semiconductor pack structure of FIG. 5A in which the semiconductor package structure comprises a single memory IC chip 110 over the electrical IC chip 108. In various embodiments, an area of the memory IC chip 110 is equal to or approximately equal to an area of the functional IC 105 of the electrical IC chip 108.

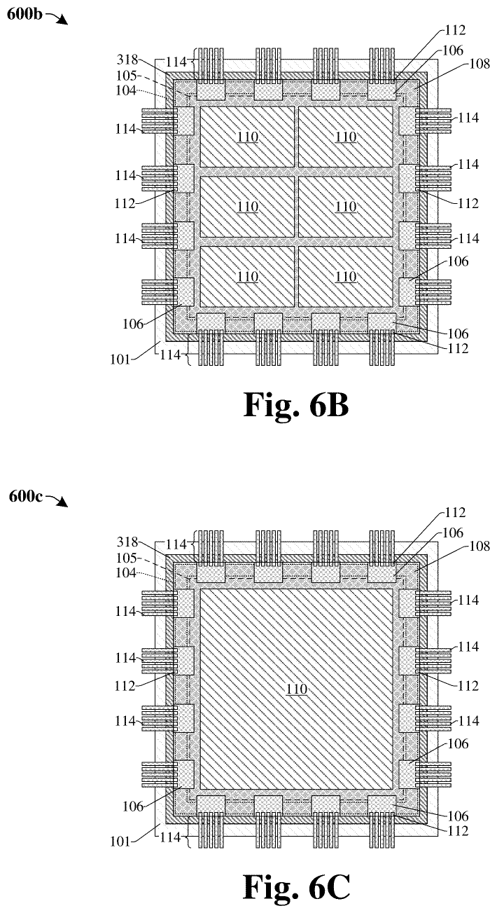

FIG. 6A illustrates a cross-sectional view 600a of some other embodiments of the semiconductor package structure of FIG. 4A in which a plurality of memory IC chips 110 directly overlies the electrical IC chip 108.

In some embodiments, the semiconductor package structure comprises a single electrical IC chip 108 overlying the interposer 103. In various embodiments, the functional IC 105 is disposed in a middle region of the electrical IC chip 108 and the EIC 104 is disposed in a peripheral region of the electrical IC chip 108. The plurality of third solder bumps 402 are disposed between the electrical IC chip 108 and the memory IC chips 110. In various embodiments, the photonic IC chips 106 directly overlie the electrical IC chip 108 and are directly laterally adjacent to the plurality of memory IC chips 110. In some embodiments, the photonic IC chips 106 and the memory IC chips 110 are disposed at a same elevation. In yet further embodiments, bottom surfaces of the photonic IC chips 106 and the memory IC chips 110 are aligned or coplanar with one another. The third solder bumps 402 provide electrical coupling between the electrical and memory IC chips 108, 110. In yet further embodiments, the third solder bumps 402 are omitted (not shown) and a bonding structure of each memory IC chip 110 directly contact a bonding structure of the electrical IC chip 108. In such embodiments, the bottom surfaces of the memory IC chips 110 directly contact a top surface of the electrical IC chip 108. Disposing the plurality of memory IC chips 110 directly over the electrical IC chip 108 increases transmission efficiency of the semiconductor package structure and decreases a power consumption of the semiconductor package structure.

FIG. 6B illustrates a top view 600b of some embodiments of the semiconductor package structure of FIG. 6A.

As illustrated in FIG. 6B, the plurality of memory IC chips 110 are spaced between opposing sidewalls of the electrical IC chip 108. In some embodiments, the EIC 104 laterally wraps around an outer perimeter of the functional IC 105. The plurality of photonic IC chips directly overlie the EIC 104 at the peripheral region of the electrical IC chip 108.

FIG. 6C illustrates a top view 600c of some other embodiments of the semiconductor pack structure of FIG. 6A in which the semiconductor package structure comprises a single memory IC chip 110 over the electrical IC chip 108.

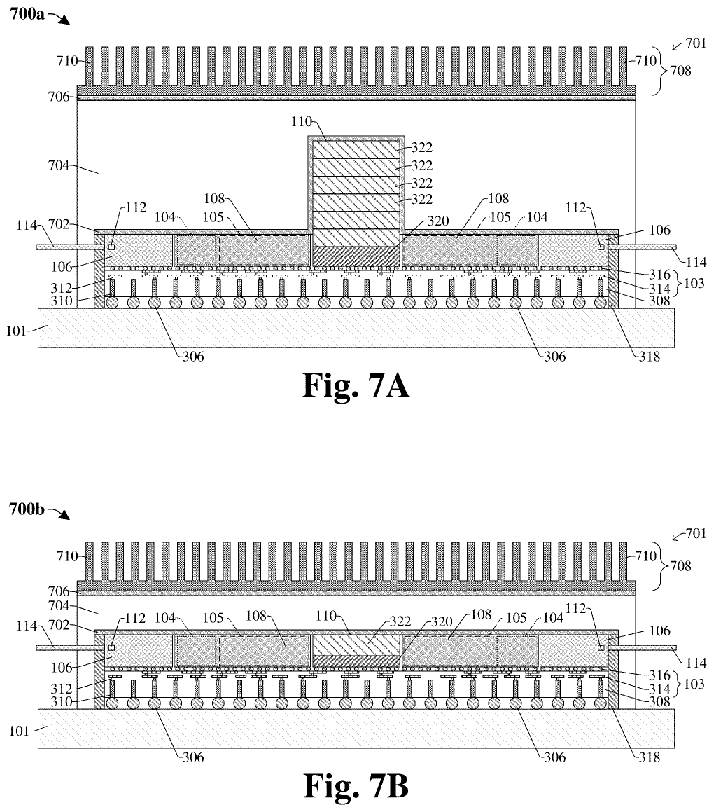

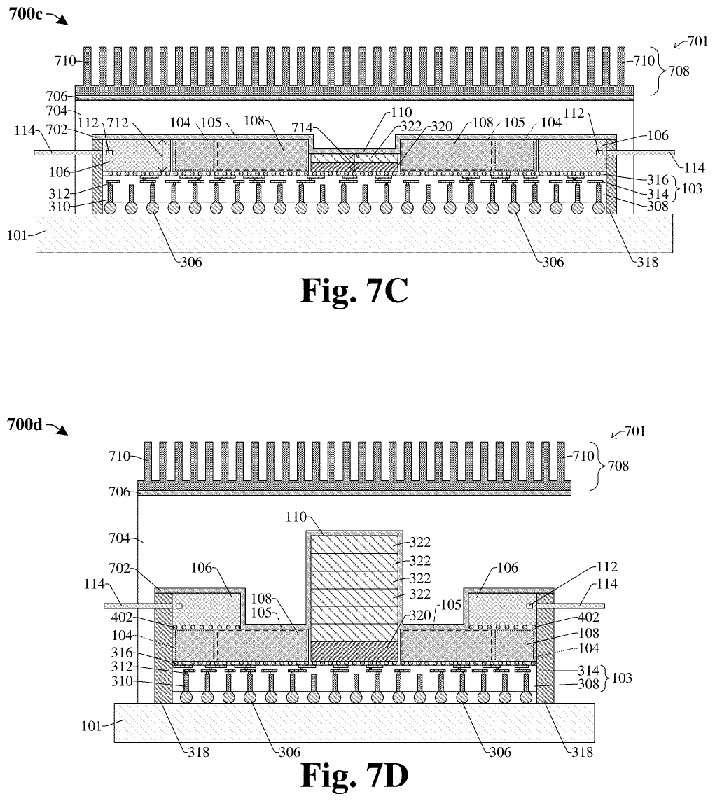

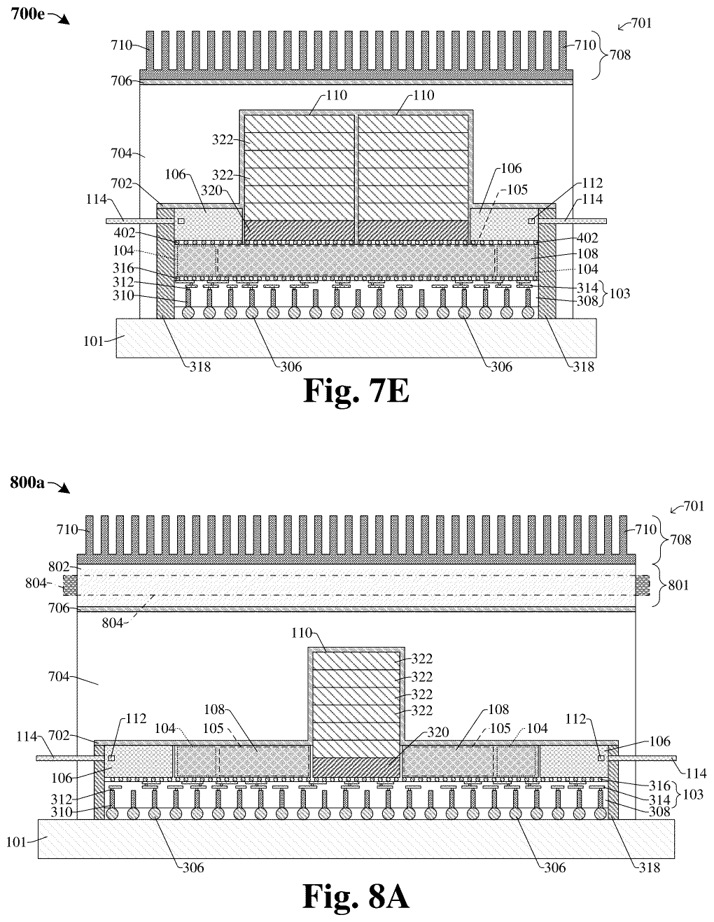

FIG. 7A illustrates a cross-sectional view 700a of some other embodiments of the semiconductor package structure of FIGS. 3A-3C in which a heat dissipation structure 701 overlies the plurality of IC chips 106, 108, 110.

In some embodiments, the heat dissipation structure 701 includes a first thermal interface layer 702, a thermal spreading layer 704, a second thermal interface layer 706, and a heat sink structure 708. The first thermal interface layer 702 is disposed between the thermal spreading layer 704 and the plurality of IC chips 106, 108, 110. In some embodiments, the first thermal interface layer 702 extends along and directly contacts a top surface of the housing structure 318 and top surfaces of the plurality of IC chips 106, 108, 110. In various embodiments, the first thermal interface layer 702 directly contacts opposing sidewalls of the memory IC chip 110. In yet further embodiments, the first thermal interface layer 702 is disposed in openings between the plurality of IC chips 106, 108, 110, such that the first thermal interface layer 702 contacts one or more sidewalls of the photonic IC chips 106 and the electrical IC chips 108 (not shown). The thermal spreading layer 704 overlies the first thermal interface layer 702 and is configured to spread and/or absorb heat from the plurality of IC chips 106, 108, 110. The thermal spreading layer 704 extends along opposing sidewalls of the housing structure 318. In some embodiments, the thermal spreading layer 704 continuously laterally wraps around the plurality of IC chips 106, 108, 110. The second thermal interface layer 706 overlies a top surface of the thermal spreading layer 704. The heat sink structure 708 overlies the second thermal interface layer 706.

In some embodiments, during operation of the semiconductor package structure the plurality of IC chips 106, 108, 110 generate heat that is directed towards the thermal spreading layer 704. The thermal spreading layer 704 is configured to spread and/or absorb the generated heat across the thermal spreading layer 704, thereby reducing a temperature of the plurality of IC chips 106, 108, 110. Heat from the plurality of IC chips 106, 108, 110 travels from the thermal spreading layer 704 to the heat sink structure 708. The heat sink structure 708 is configured to dissipate the heat from the plurality of IC chips 106, 108, 110, thereby reducing a temperature of the semiconductor package structure. For example, the heat sink structure 708 comprises a plurality of heat sink fins 710 vertically extending from a base of the heat sink structure 708 in a direction away from the package substrate 101. The heat sink fins 710 are laterally spaced from one another. Air may travel between the heat sink fins 710 and dissipate the heat collected at and/or cool the heat sink fins 710. For example, a fan (not shown) may be configured to direct air between the heat sink fins 710 to carry heat away from the heat sink structure 708, thereby reducing a temperature of the heat sink structure 708. As a result, the heat dissipation structure 701 reduces a temperature of the semiconductor package structure, thereby increasing a reliability.

Further, the photonic IC chips 106 are disposed at a peripheral region of the interposer 103 and include the optical I/O structures 112 (e.g., edge couplers) configured to receive optical signals along sides of the semiconductor package structure. This facilitates the transmission and/or receiving of optical signals in the horizontal direction, such that the heat dissipation structure 701 may be disposed directly over the plurality of IC chips 106, 108, 110. As a result, the heat dissipation structure 701 may efficiently dissipate heat generated by the plurality of IC chips 106, 108, 110. Thus, a location and/or layout of the photonic IC chips 106 increases transmission efficiency of the semiconductor package structure while increasing an ability to dissipate heat away from the semiconductor package structure, thereby increasing an overall performance of the semiconductor package structure.

In some embodiments, the first and second thermal interface layers 702, 706 may, for example, be or comprise a polymer, wax, aluminum, a viscous silicone compound, or any combination of the foregoing. In some embodiments, the viscous silicone compound has mechanical properties similar to that of a grease or a gel. In various embodiments, the thermal spreading layer 704 may, for example, be or comprise a metal, such as aluminum, copper, nickel, cobalt, some other metal, or an alloy thereof. In further embodiments, the thermal spreading layer 704 may, for example, be or comprise a composite material from the group consisting of silicon carbide, aluminum nitride, graphite, or the like. In some embodiments, the heat sink structure 708 may, for example, be or comprise copper, aluminum, some other material, or any combination of the foregoing.

FIG. 7B illustrates a cross-sectional view 700b of some other embodiments of the semiconductor package structure of FIG. 7A in which a height of the memory IC chip 110 is equal to heights of the photonic and electrical IC chips 106, 108. In some embodiments, a top surface of the memory IC chip 110 is coplanar with top surfaces of the photonic and electrical IC chips 106, 108. This, in part, facilitates decreasing an overall height of the semiconductor package structure and/or increases an ability to dissipate heat from the plurality of IC chips 106, 108, 110.

FIG. 7C illustrates a cross-sectional view 700c of some other embodiments of the semiconductor package structure of FIG. 7A in which a height 714 of the memory IC chip 110 is less than heights of the photonic and electrical IC chips 106, 108. In some embodiments, the height 714 of the memory IC chip 110 is less than a height 712 of the photonic IC chips 106. In various embodiments, the height of the electrical IC chips 108 is equal to the height 712 of the photonic IC chips 106.

FIG. 7D illustrates a cross-sectional view 700d of some other embodiments of the semiconductor package structure of FIGS. 4A-4C in which a heat dissipation structure 701 overlies the plurality of IC chips 106, 108, 110. In some embodiments, the heat dissipation structure 701 is configured as illustrated and/or described in FIG. 7A above.

FIG. 7E illustrates a cross-sectional view 700e of some other embodiments of the semiconductor package structure of FIGS. 6A-6C in which a heat dissipation structure 701 overlies the plurality of IC chips 106, 108, 110. In some embodiments, the heat dissipation structure is configured as illustrated and/or described in FIG. 7A above. In various embodiments, the first thermal interface layer 702 is disposed directly between adjacent memory IC chips 110 and between the memory IC chips 110 and the photonic IC chips 106.

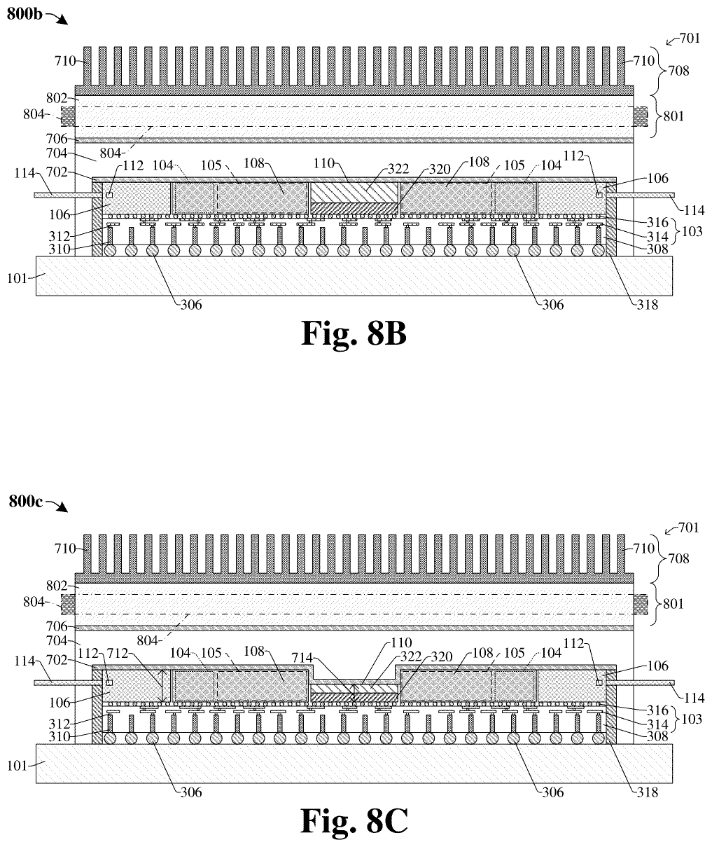

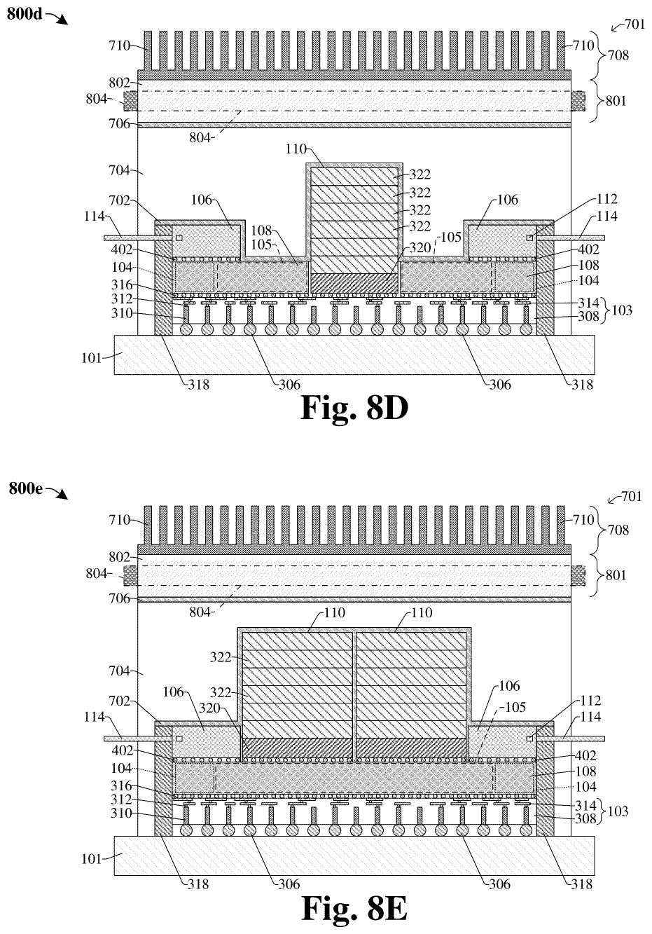

FIGS. 8A-8E illustrate cross-sectional views 800a-800e of some other embodiments of the semiconductor package structure of FIGS. 7A-7E in which the heat dissipation structure 701 further includes a liquid cooling structure 801 disposed on the second thermal interface layer 706. For instance, FIG. 8A illustrates a cross-sectional view 800a corresponding to some other embodiments of the semiconductor package structure of FIG. 7A, FIG. 8B illustrates a cross-sectional view 800b corresponding to some other embodiments of the semiconductor package structure of FIG. 7B, FIG. 8C illustrates a cross-sectional view 800c corresponding to some other embodiments of the semiconductor package structure of FIG. 7C, and so on.

In some embodiments, the liquid cooling structure 801 is disposed between the heat sink structure 708 and the second thermal interface layer 706. The liquid cooling structure 801 includes a liquid housing structure 802 and a liquid channel structure 804. The liquid channel structure 804 is disposed in the liquid housing structure 802. In some embodiments, during operation of the heat dissipation structure 701 a liquid pump (not shown) is configured to circulate a liquid (e.g., water or another coolant) across the liquid channel structure 804. The liquid absorbs heat generated from the plurality of IC chips 106, 108, 110 and is configured to be transported away to an external cooler or heat exchanger (not shown) and/or is configured to be cooled by the overlying heat sink structure 708. This facilitates further reducing a temperature of the plurality of IC chips 106, 108, 110, thereby further increasing an overall performance of the semiconductor package structure. In yet further embodiments, the heat sink structure 708 may be omitted from the semiconductor package structures of FIGS. 8A-8E (not shown).

FIGS. 9-17 illustrate cross-sectional views 900-1700 of some embodiments of a method for forming a semiconductor package structure that includes a photonic IC chip directly adjacent to an electrical IC chip. Although the cross-sectional views 900-1700 shown in FIGS. 9-17 are described with reference to a method, it will be appreciated that the structures shown in FIGS. 9-17 are not limited to the method but rather may stand alone separate of the method. Furthermore, although FIGS. 9-17 are described as a series of acts, it will be appreciated that these acts are not limited in that the order of the acts can be altered in other embodiments, and the methods disclosed are also applicable to other structures. In other embodiments, some acts that are illustrated and/or described may be omitted in whole or in part.

As shown in cross-sectional view 900 of FIG. 9, an interposer 103 is provided or otherwise formed over a carrier substrate 902. In some embodiments, the interposer 103 includes an interposer structure 308, a plurality of through substrate vias (TSVs) 310, a plurality of conductive interconnect structures 312, 314, and a plurality of contact pads 315. A plurality of first solder bumps 306 are formed on a lower surface of the interposer 103. The plurality of first solder bumps 306 may be or comprise solder bumps, micro-bumps, copper posts, or some other suitable bump structures.

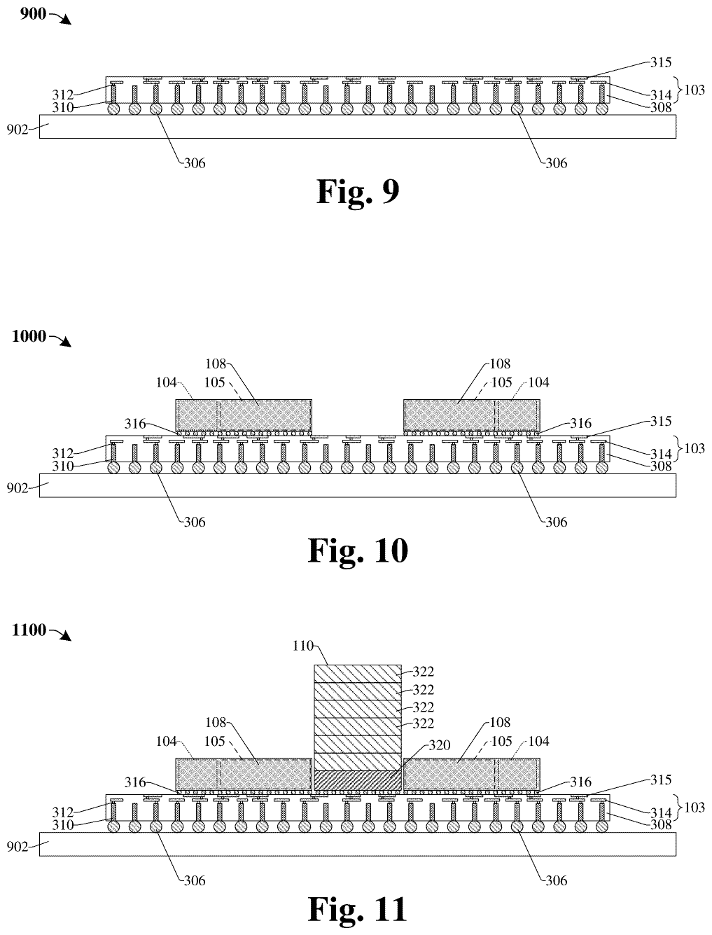

As shown in cross-sectional view 1000 of FIG. 10, one or more electrical IC chips 108 is/are provided or otherwise formed, and are arranged over and bonded to the contact pads 315 of the interposer 103. In some embodiments, the one or more electrical IC chips 108 are configured as a system-on-chip (SoC) chip and include an electrical integrated circuit (EIC) 104 and a functional IC 105. In various embodiments, bonding the one or more electrical IC chips 108 to the interposer 103 includes forming a plurality of second solder bumps 316 over the interposer 103 and performing a bonding process (e.g., a soldering process). In yet further embodiments, the one or more electrical IC chips 108 are bonded to the interposer 103 by way of a cutectic bonding process or some other suitable bonding process. The plurality of second solder bumps 316 may, for example, be or comprise solder bumps, micro-bumps, copper posts, or some other suitable bump structure. In some embodiments, the EIC 104 comprises circuitry including amplifiers, control circuits, digital processing circuits, drivers, etc. for a photonic IC chip. The functional IC 105 may, for example, be or comprise one or more of a switch chip, an ASIC, a CPU, a GPU, a DPU, and so on.

As shown in cross-sectional view 1100 of FIG. 11, one or more memory IC chips 110 is/are provided or otherwise formed, and are arranged over and bonded to the contact pads 315 of the interposer 103. In some embodiments, the one or more memory IC chips 110 are or comprise a plurality of memory layers 322 vertically stacked with a memory controller circuit 320. In various embodiments, bonding the one or more memory IC chips 110 to the interposer 103 includes forming a plurality of second solder bumps 316 over the interposer 103 and performing a bonding process (e.g., a soldering process). In yet further embodiments, the one or more memory IC chips 110 are bonded to the interposer 103 by way of a cutectic bonding process or some other suitable bonding process. The one or more memory IC chips 110 is/are arranged over the interposer 103 such that the one or more memory IC chips 110 is/are directly adjacent to the one or more electrical IC chips 108. In various embodiments, the one or more electrical IC chips 108 laterally surround and/or are directly laterally adjacent to the one or more memory IC chips 110. In yet further embodiments, the one or more memory IC chips 110 directly overlie and are bonded directly to the one or more electrical IC chips 108 (not shown) (e.g., as illustrated and/or described in FIG. 5A-5C or 6A-6C).

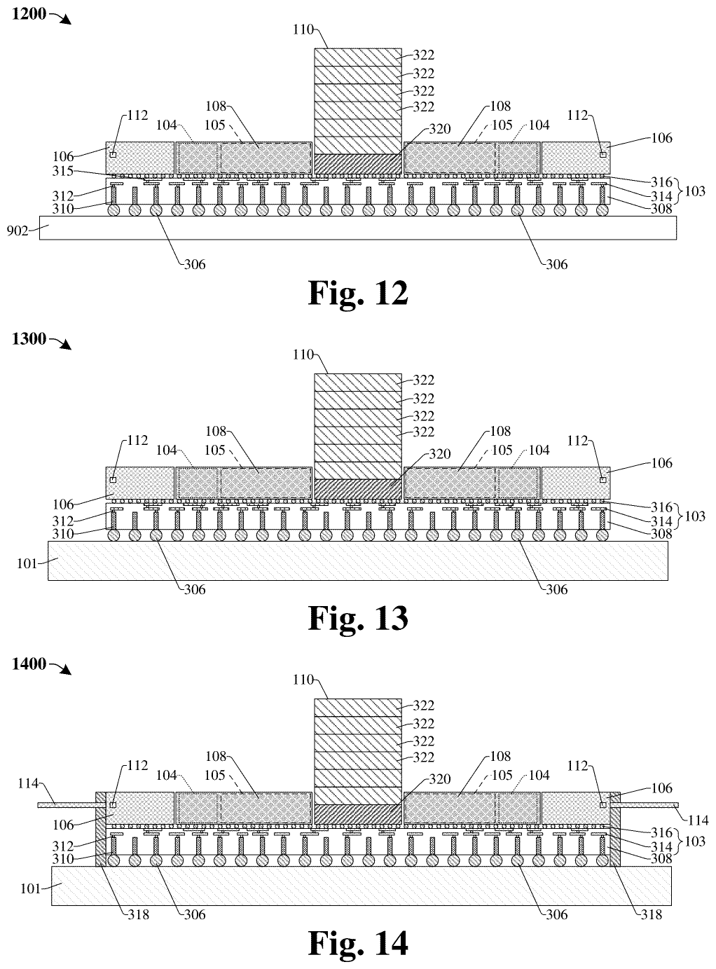

As shown in cross-sectional view 1200 of FIG. 12, a plurality of photonic IC chips 106 are provided or otherwise formed, and are arranged over and bonded to the contact pads 315 of the interposer 103. In some embodiments, the photonic IC chips 106 comprise one or more optical I/O structures 112 and other photonic devices such as waveguides, photodetectors, light emitting units (e.g., laser diodes, light emitting diodes, etc.), optical modulators, other photonic devices, or any combination of the foregoing. In various embodiments, bonding the plurality of photonic IC chips 106 to the interposer 103 includes forming a plurality of second solder bumps 316 over the interposer and performing a bonding process (e.g., a soldering process). In yet further embodiments, the photonic IC chips 106 are bonded to the interposer 103 by way of a cutectic bonding process or some other suitable bonding process. The photonic IC chips 106 are disposed at a peripheral of the interposer 103 and are directly adjacent to the one or more electrical IC chips 108. In some embodiments, the photonic IC chips 106 are directly adjacent to the one or more electrical IC chips 108. In yet further embodiments, the photonic IC chips 106 directly overlie and are bonded directly to the one or more electrical IC chips 108 (not shown) (e.g., as illustrated and/or described in FIG. 4A-4C, 5A-5C, or 6A-6C). Disposing the photonic IC chips 106 directly adjacent to the one or more electrical IC chips 108 increases a transmission efficiency of the semiconductor package structure. Further, in some embodiments, a top layout of the semiconductor package structure is configured as shown in FIG. 3B, 3C, 4B, 4C, 5B, 5C, 6B, or 6C.

As shown in cross-sectional view 1300 of FIG. 13, the carrier substrate (902 of FIG. 12) is removed and the interposer 103 is bonded to a package substrate 101. In some embodiments, the interposer 103 is bonded to the package substrate 101 by, for example, a soldering process or some other suitable process.

As shown in cross-sectional view 1400 of FIG. 14, a plurality of optical fiber structures 114 are formed adjacent to and/or attached next to the optical I/O structures 112 of the photonic IC chips 106. Further, a housing structure 318 is formed over the package substrate 101 and around the interposer 103. The housing structure 318 is disposed along a sidewall of each photonic IC chip 106 and provides support for the plurality of optical fiber structures, where the housing structure 318 provides support for the optical fiber structures 114. In various embodiments, the housing structure 318 may, for example, be epoxy or some other suitable material.

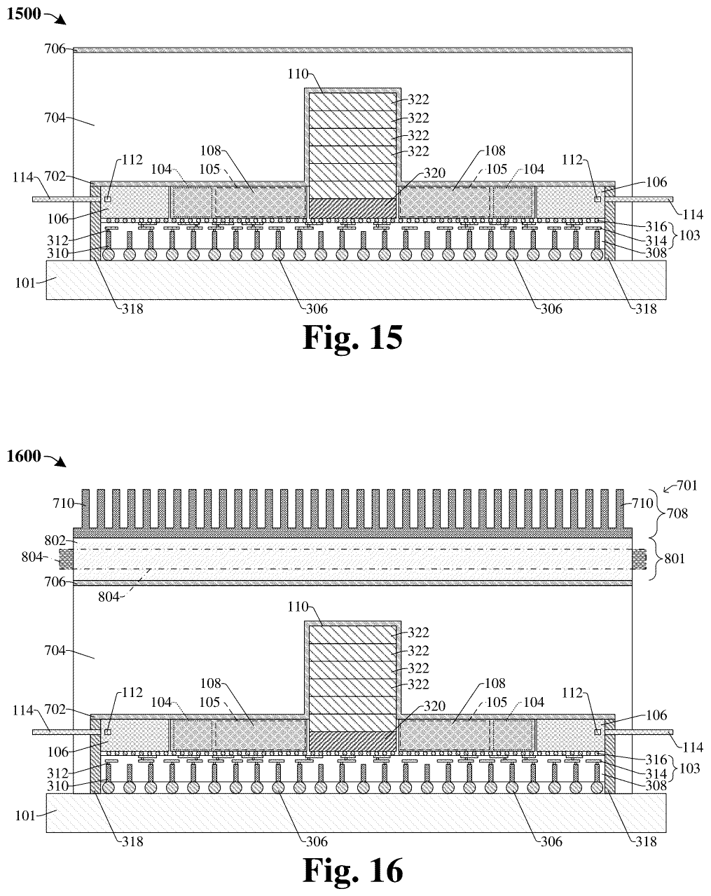

As shown in cross-sectional view 1500 of FIG. 15, a first thermal interface layer 702 is formed over the package substrate 101, a thermal spreading layer 704 is formed over the first thermal interface layer 702, and a second thermal interface layer 706 is formed over the thermal spreading layer 704. In various embodiments, the first and second thermal interface layers 702, 706 may, for example, be formed by a screen-printing process, a spraying process, a paste or grease application process, a sputtering process, a physical vapor deposition (PVD) process, or some other suitable fabrication process. In yet further embodiments, the thermal spreading layer 704 may, for example, be formed by a screen-printing process, a lamination process, a deposition process (e.g., a PVD process), or some other suitable fabrication process.

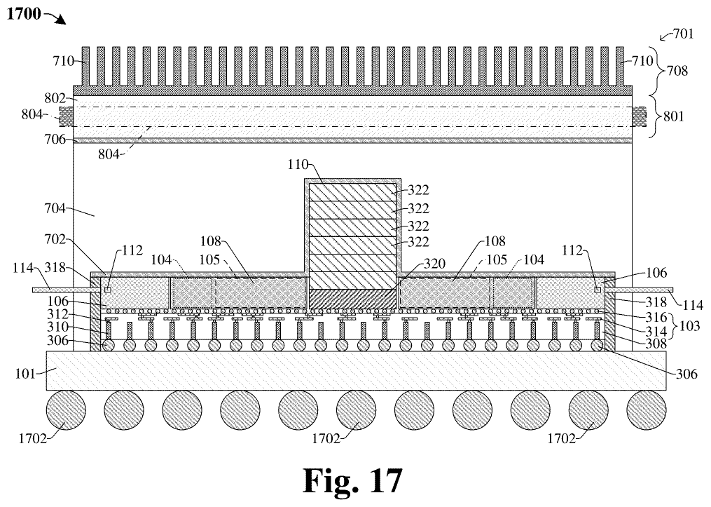

As shown in cross-sectional view 1600 of FIG. 16, a liquid cooling structure 801 is formed over the second thermal interface layer 706 and a heat sink structure 708 is formed over the liquid cooling structure 801, thereby defining a heat dissipation structure 701. The liquid cooling structure 801 includes a liquid housing structure 802 and a liquid channel structure 804. The heat sink structure 708 includes a plurality of heat sink fins 710 extending upward from a base of the heat sink structure 708. In some embodiments, forming the heat dissipation structure 701 includes the processing and/or fabrication steps illustrated and/or described in FIGS. 15 and 17.

As shown in cross-sectional view 1700 of FIG. 17, a plurality of lower solder bumps 1702 are formed along a lower surface of the package substrate 101.

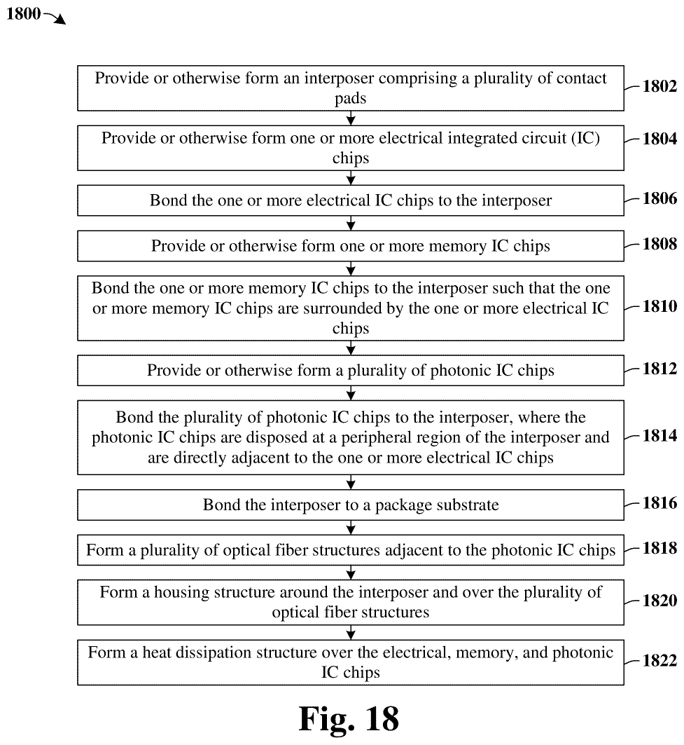

FIG. 18 illustrates a flow diagram of some embodiments of a method 1800 of forming a semiconductor package structure that includes a photonic IC chip directly adjacent to an electrical IC chip. Although the method 1800 is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 1802, an interposer comprising a plurality of contact pads is provided or otherwise formed. FIG. 9 illustrates a cross-sectional view 900 corresponding to some embodiments of act 1802.

At act 1804, one or more electrical integrated circuit (IC) chips are provided or otherwise formed.

At act 1806, the one or more electrical IC chips are bonded to the interposer. FIG. 10 illustrates a cross-sectional view 1000 corresponding to some embodiments of acts 1804 and 1806.

At act 1808, one or more memory IC chips are provided or otherwise formed.

At act 1810, the one or more memory IC chips are bonded to the interposer such that the one or more memory IC chips are surrounded by the one or more electrical IC chips. FIG. 11 illustrates a cross-sectional view 1100 corresponding to some embodiments of acts 1808 and 1810.

At act 1812, a plurality of photonic IC chips are provided or otherwise formed.

At act 1814, the plurality of photonic IC chips are bonded to the interposer, where the photonic IC chips are disposed at a peripheral region of the interposer and are directly adjacent to the one or more electrical IC chips. FIG. 12 illustrates a cross-sectional view 1200 corresponding to some embodiments of acts 1812 and 1814.

At act 1816, the interposer is bonded to a package substrate. FIG. 13 illustrates a cross-sectional view 1300 corresponding to some embodiments of act 1816.

At act 1818, a plurality of optical fiber structures are formed adjacent to the photonic IC chips.

At act 1820, a housing structure is formed around the interposer and over the plurality of optical fiber structures. FIG. 14 illustrates a cross-sectional view 1400 corresponding to some embodiments of acts 1818 and 1820.

At act 1822, a heat dissipation structure is formed over the electrical, memory, and photonic IC chips. FIGS. 15 and 16 illustrate cross-sectional views 1500 and 1600 corresponding to some embodiments of act 1822.

Accordingly, in some embodiments, the present disclosure relates to a semiconductor package structure comprising an electrical IC chip over a package substrate and a photonic IC overlying the package substrate and directly adjacent to the electrical IC chip.

In some embodiments, the present application provides a semiconductor package structure, including: a first integrated circuit (IC) chip overlying a base structure; an electrical IC chip overlying the base structure and disposed around the first IC chip, wherein the electrical IC chip is electrically coupled to the first IC chip; and a photonic IC chip overlying the base structure and electrically coupled to the electrical IC chip, wherein the photonic IC chip is configured to receive an input optical signal, wherein the photonic IC chip is adjacent to the electrical IC chip. In an embodiment, the first IC chip is configured as a memory IC chip and the photonic IC chip is disposed at a same elevation as the electrical IC chip and the first IC chip. In an embodiment, a bottom surface of the photonic IC chip is coplanar with a bottom surface of the electrical IC chip. In an embodiment, the photonic IC chip directly overlies the electrical IC chip. In an embodiment, the photonic IC chip comprises an optical input/output (I/O) structure disposed at a peripheral region of the photonic IC chip, a waveguide optically coupled to the I/O structure, and a photodetector optically coupled to the waveguide, wherein the I/O structure is configured to receive the input optical signal, and wherein the photodetector is configured to convert the input optical signal to an electrical signal. In an embodiment, the electrical IC chip comprises an electrical integrated circuit (EIC) and a functional IC laterally adjacent to the EIC, wherein the EIC comprises one or more electrical components configured to receive the electrical signal from the photonic IC chip and generate an output electrical signal, wherein the functional IC is configured to receive the output electrical signal, wherein the EIC is spaced directly between the functional IC and the photonic IC chip. In an embodiment, the one or more electrical components comprises one or more of an amplifier circuit and/or a driver circuit, and wherein the functional IC comprises one or more of a central processing unit (CPU), a graphics processing unit (GPU), and/or a data processing unit (DPU), wherein the EIC is configured to provide an electrical interface between the functional IC and the photonic IC chip. In an embodiment, the semiconductor package structure further comprises an optical fiber structure attached to the photonic IC chip and coupled to the optical I/O structure, wherein the optical fiber structure is elongated in a first direction parallel to an upper surface of the base structure. In an embodiment, the semiconductor package structure further comprises a heat dissipation structure overlying the first, electrical, and photonic IC chips, wherein the heat dissipation structure comprises a thermal spreading layer over the first, electrical, and photonic IC chips and a heat sink structure over the thermal spreading layer.

In some embodiments, the present application provides a semiconductor package structure, including: an interposer overlying a package substrate; one or more electrical integrated circuit (IC) chips overlying and coupled to the interposer; a first IC chip overlying the interposer and coupled to the one or more electrical IC chips, wherein the first IC chip is spaced laterally between opposing sidewalls of the one or more electrical IC chips; and a plurality of photonic IC chips overlying the interposer and electrically coupled to the one or more electrical IC chips, wherein the plurality of photonic IC chips are disposed at a peripheral region of the interposer and surround the first IC chip, wherein a lateral distance between each photonic IC chip in the plurality of photonic IC chips and the one or more electrical IC chips is less than a width of an individual photonic IC chip in the plurality of photonic IC chips. In an embodiment, bottom surfaces of the electrical, first, and photonic IC chips are substantially coplanar with one another, wherein the one or more electrical IC chips laterally wrap around an outer perimeter of the first IC chip, and wherein the photonic IC chips are spaced between an outer perimeter of the one or more electrical IC chips and an outer perimeter of the interposer. In an embodiment, the plurality of photonic IC chips directly overlie the one or more electrical IC chips, wherein an outer sidewall of each photonic IC chip is aligned with a corresponding sidewall of the one or more electrical IC chips. In an embodiment, the plurality of photonic IC chips comprises a first photonic IC chip adjacent to a second photonic IC chip, wherein a first distance between the first photonic IC chip and the second photonic IC chip is less than the lateral distance. In an embodiment, the one or more electrical IC chips comprise a single electrical IC chip disposed over a middle region of the interposer, wherein the first IC chip directly overlies the single electrical IC chip, wherein the plurality of photonic IC chips are disposed over a peripheral region of the interposer, wherein the photonic IC chips are adjacent to four sides of the single electrical IC chip. In an embodiment, the one or more electrical IC chips comprises a single electrical IC chip over the interposer, wherein the first IC chip directly overlies a middle region of the single electrical IC chip, wherein the plurality of photonic IC chips directly overlie a peripheral region of the single electrical IC chip, wherein the plurality of photonic IC chips surround the first IC chip. In an embodiment, the semiconductor package structure further includes a housing structure disposed around an outer perimeter of the interposer, wherein the housing structure extends from a sidewall of the interposer, along a sidewall of the single electrical IC chip, to a sidewall of each photonic IC chip; and a plurality of optical fiber structures attached to the plurality of photonic IC chips, wherein the optical fiber structures are disposed in the housing structure. In an embodiment, the plurality of photonic IC chips respectively comprise a plurality of edge couplers vertically aligned with the plurality of optical fiber structures. In an embodiment, the first IC chip is configured as a memory IC chip and the lateral distance is less than half of the width of the individual photonic IC chip in the plurality of photonic IC chips.

In some embodiments, the present application provides a method for forming a semiconductor package structure, the method includes: bonding one or more electrical integrated circuit (IC) chips to an interposer; bonding a memory IC chip to the interposer, wherein the memory IC chip is spaced between sidewalls of the one or more electrical IC chips; and bonding a plurality of photonic IC chips to the interposer, wherein the plurality of photonic IC chips are configured to receive an input optical signal and generate an electrical signal corresponding to the input optical signal, wherein the photonic IC chips are disposed adjacent to the one or more electrical IC chips, wherein the one or more electrical IC chips are configured to receive the generated electrical signal. In an embodiment, the method further includes attaching a plurality of optical fiber structures to the plurality of photonic IC chips, wherein the plurality of photonic IC chips are spaced directly between the plurality of optical fiber structures and the one or more electrical IC chips.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package structure, comprising:
a first integrated circuit (IC) chip overlying a base structure;
an electrical IC chip overlying the base structure and disposed around the first IC chip, wherein the electrical IC chip is electrically coupled to the first IC chip; and
a photonic IC chip overlying the base structure and electrically coupled to the electrical IC chip, wherein the photonic IC chip is configured to receive an input optical signal, wherein the photonic IC chip is adjacent to the electrical IC chip.

2. The semiconductor package structure of claim 1, wherein the first IC chip is configured as a memory IC chip, wherein the photonic IC chip is disposed at a same elevation as the electrical IC chip and the first IC chip.

3. The semiconductor package structure of claim 2, wherein a bottom surface of the photonic IC chip is coplanar with a bottom surface of the electrical IC chip.

4. The semiconductor package structure of claim 1, wherein the photonic IC chip directly overlies the electrical IC chip.

5. The semiconductor package structure of claim 1, wherein the photonic IC chip comprises an optical input/output (I/O) structure disposed at a peripheral region of the photonic IC chip, a waveguide optically coupled to the I/O structure, and a photodetector optically coupled to the waveguide, wherein the I/O structure is configured to receive the input optical signal, and wherein the photodetector is configured to convert the input optical signal to an electrical signal.

6. The semiconductor package structure of claim 5, wherein the electrical IC chip comprises an electrical integrated circuit (EIC) and a functional IC laterally adjacent to the EIC, wherein the EIC comprises one or more electrical components configured to receive the electrical signal from the photonic IC chip and generate an output electrical signal, wherein the functional IC is configured to receive the output electrical signal, wherein the EIC is spaced directly between the functional IC and the photonic IC chip.

7. The semiconductor package structure of claim 6, wherein the one or more electrical components comprises one or more of an amplifier circuit and/or a driver circuit, and wherein the functional IC comprises one or more of a central processing unit (CPU), a graphics processing unit (GPU), and/or a data processing unit (DPU), wherein the EIC is configured to provide an electrical interface between the functional IC and the photonic IC chip.

8. The semiconductor package structure of claim 5, further comprising:
an optical fiber structure attached to the photonic IC chip and coupled to the optical I/O structure, wherein the optical fiber structure is elongated in a first direction parallel to an upper surface of the base structure.

9. The semiconductor package structure of claim 8, further comprising:
a heat dissipation structure overlying the first, electrical, and photonic IC chips, wherein the heat dissipation structure comprises a thermal spreading layer over the first, electrical, and photonic IC chips and a heat sink structure over the thermal spreading layer.

10. A semiconductor package structure, comprising:
an interposer overlying a package substrate;
one or more electrical integrated circuit (IC) chips overlying and coupled to the interposer;
a first IC chip overlying the interposer and coupled to the one or more electrical IC chips, wherein the first IC chip is spaced laterally between opposing sidewalls of the one or more electrical IC chips; and
a plurality of photonic IC chips overlying the interposer and electrically coupled to the one or more electrical IC chips, wherein the plurality of photonic IC chips are disposed at a peripheral region of the interposer and surround the first IC chip, wherein a lateral distance between each photonic IC chip in the plurality of photonic IC chips and the one or more electrical IC chips is less than a width of an individual photonic IC chip in the plurality of photonic IC chips.

11. The semiconductor package structure of claim 10, wherein bottom surfaces of the electrical, first, and photonic IC chips are substantially coplanar with one another, wherein the one or more electrical IC chips laterally wrap around an outer perimeter of the first IC chip, and wherein the photonic IC chips are spaced between an outer perimeter of the one or more electrical IC chips and an outer perimeter of the interposer.

12. The semiconductor package structure of claim 10, wherein the plurality of photonic IC chips directly overlie the one or more electrical IC chips, wherein an outer sidewall of each photonic IC chip is aligned with a corresponding sidewall of the one or more electrical IC chips.

13. The semiconductor package structure of claim 10, wherein the plurality of photonic IC chips comprises a first photonic IC chip adjacent to a second photonic IC chip, wherein a first distance between the first photonic IC chip and the second photonic IC chip is less than the lateral distance.

14. The semiconductor package structure of claim 10, wherein the one or more electrical IC chips comprise a single electrical IC chip disposed over a middle region of the interposer, wherein the first IC chip directly overlies the single electrical IC chip, wherein the plurality of photonic IC chips are disposed over a peripheral region of the interposer, wherein the photonic IC chips are adjacent to four sides of the single electrical IC chip.

15. The semiconductor package structure of claim 10, wherein the one or more electrical IC chips comprises a single electrical IC chip over the interposer, wherein the first IC chip directly overlies a middle region of the single electrical IC chip, wherein the plurality of photonic IC chips directly overlie a peripheral region of the single electrical IC chip, wherein the plurality of photonic IC chips surround the first IC chip.

16. The semiconductor package structure of claim 15, further comprising:
a housing structure disposed around an outer perimeter of the interposer, wherein the housing structure extends from a sidewall of the interposer, along a sidewall of the single electrical IC chip, to a sidewall of each photonic IC chip; and
a plurality of optical fiber structures attached to the plurality of photonic IC chips, wherein the optical fiber structures are disposed in the housing structure.

17. The semiconductor package structure of claim 16, wherein the plurality of photonic IC chips respectively comprise a plurality of edge couplers vertically aligned with the plurality of optical fiber structures.

18. The semiconductor package structure of claim 10, wherein the first IC chip is configured as a memory IC chip, wherein the lateral distance is less than half of the width of the individual photonic IC chip in the plurality of photonic IC chips.

19. A method of forming a semiconductor package structure, comprising:
bonding one or more electrical integrated circuit (IC) chips to an interposer;
bonding a memory IC chip to the interposer, wherein the memory IC chip is spaced between sidewalls of the one or more electrical IC chips; and
bonding a plurality of photonic IC chips to the interposer, wherein the plurality of photonic IC chips are configured to receive an input optical signal and generate an electrical signal corresponding to the input optical signal, wherein the photonic IC chips are disposed adjacent to the one or more electrical IC chips, wherein the one or more electrical IC chips are configured to receive the generated electrical signal.

20. The method of claim 19, further comprising:
attaching a plurality of optical fiber structures to the plurality of photonic IC chips, wherein the plurality of photonic IC chips are spaced directly between the plurality of optical fiber structures and the one or more electrical IC chips.
